(19) United States
(12) Patent Application Publication
(10) Pub. No.: US 2010/0068648 A1
(43) Pub. Date: Mar. 18, 2010

(54) PHOTOSENSITIVE RESIN COMPOSITION, AND RESIST PATTERN FORMATION METHOD USING THE SAME

(75) Inventors: Takahiro Senzaki, Kanagawa (JP); Koichi Misumi, Kanagawa (JP); Atsushi Yamanouchi, Kanagawa (JP); Koji Saito, Kanagawa (JP)

Correspondence Address: WENDEROTH, LIND & PONACK, L.L.P., 1030 15th Street, N.W.,, Suite 400 East, Washington, DC, 20005-1503, US

(73) Assignee: TOKYO OHKA KOGYO CO., LTD.

(21) Appl. No.: 12/448,913

(22) PCT Filed: Jan. 11, 2008
(86) PCT No.: PCT/JP2008/050235

§ 371 Date: Jul. 15, 2009

(30) Foreign Application Priority Data
Jan. 24, 2007 (JP) 2007-013800

(51) Int. Cl. G03F 7/20; G03F 7/004

(52) U.S. Cl. 430/280.1; 430/325

(57) ABSTRACT

A photosensitive resin composition capable of controlling occurrence of defects and capable of forming a resist pattern having a favorable configuration, and a method for forming a resist pattern using the same are provided. According to a photosensitive resin composition including, as component (a), a polyfunctional epoxy resin, and, as component (b), a cation polymerization initiator, in which the concentration of propylene carbonate in the photosensitive resin composition is no greater than 10% by mass, the occurrence of defects can be controlled, and a resist pattern having a favorable shape can be formed.

### TECHNICAL FIELD

The present invention relates to a photosensitive resin composition, and a method for forming a resist pattern using the same, and more particularly, relates to a photosensitive resin composition capable of controlling occurrence of defects and capable of forming a favorable pattern configuration, and to a method for forming a resist pattern using the same.

### BACKGROUND ART

In recent years, MEMS (Micro Electro Mechanical System) which has been attracting attention as a mass production system that realizes high performance and a high degree of integration by integrating minute parts within a single chip utilizing a semiconductor manufacturing technology is expected for development in a variety of fields such as fields of information and telecommunications, as well as automobiles, consumer appliances, and medical and bio-related fields. Demands for downsizing in each of these fields have been increasingly growing, and exploitation of a photosensitive resin composition capable of forming a micro resist pattern having a large film thickness and a high aspect ratio has been desired.

However, conventional photosensitive resin compositions including a novolac resin and diazonaphthoquinone as a photoacid generator could not provide a profile having a high aspect ratio in the case with a large film thickness. This results from the diazonaphthoquinone type photoacid generator that exhibits high absorption of near ultra violet light used in exposure, leading to large difference in exposure intensity between the top and bottom of a thick film, whereby the resulting resin pattern has a tapered or curved profile as a consequence.

Taking into consideration such circumstances, a photosensitive resin composition containing an epoxy resin and an acid generator was proposed as a photosensitive resin composition capable of forming a micro resist pattern with a high aspect ratio. Specifically, a photosensitive resin composition including an epoxy-functional novolac resin, an acid generator such as a triarylsulfonium salt, and a diluent capable of reacting with an epoxy-reactive group is disclosed (for example, see Patent Document 1). Furthermore, a photosensitive resin composition including a polyfunctional bisphenol A formaldehyde-novolac resin, triphenylsulfonium hexafluoroantimonate as an acid generator, and a cyclopentanone solvent, and capable of forming a thick film is disclosed (for example, see Patent Document 2).

On the other hand, photosensitive resin compositions that provide high sensitivity and high resolving ability were proposed in addition to the diazonaphthoquinone type photoacid generator. For example, a photosensitive resin composition prepared using an aromatic sulfonium cation polymerization initiator is disclosed (see for example, Patent Documents 3 and 4). Moreover, a permanent film resist composition containing a cation polymerization initiator that absorbs exposure light of a wavelength of 360 nm or longer is disclosed (see for example, Patent Document 5).

The aforementioned photocation polymerization initiator is generally constituted with a cation component and an anion component. Examples of the anion component include SbF₆⁻, AsF₆⁻, PF₆⁻, BF₄⁻ and the like, and known order of the sensitivity is represented by SbF₆⁻>AsF₆⁻>PF₆⁻>BF₄⁻. Thus, antimony (Sb) based, or arsenic (As) based cation polymerization initiators that are highly sensitive have been widely used.

As the cation polymerization initiator including neither antimony nor arsenic, onium fluorinated alkyl fluorophosphates are disclosed (see for example, Patent Document 6).

Patent Document 1: Japanese Examined Patent Application Publication No. H07-78628

Patent Document 2: U.S. Pat. No. 6,391,523

Patent Document 3: Japanese Unexamined Patent Application Publication No. H09-268205

Patent Document 4: Japanese Unexamined Patent Application Publication No. 2005-055865

Patent Document 5: Japanese Unexamined Patent Application Publication No. H10-097068

Patent Document 6: International Publication No. 2005/116038

### DISCLOSURE OF THE INVENTION

### Problems to be Solved by the Invention

Meanwhile, although still further micro-fabrication, and high resolving ability of resist patterns have been desired, the resist pattern obtained by pattern formation using a photosensitive resin composition may be accompanied by defects of pattern surface configuration for any reason. Specifically, there are problems of occurrence of defects such as surface roughness on a part of the pattern surface, and the causes have not been elucidated heretofore. Since such defects of surface configuration of the pattern may account for reduction of yield of semiconductor elements, these are significant problems to be solved.

The present invention was made in view of the above problems, and an object of the present invention is to provide a photosensitive resin composition capable of controlling occurrence of defects and capable of forming a favorable pattern configuration, and a method for forming a resist pattern using the same.

### Means for Solving the Problems

In order to solve the abovementioned problems, the present inventors have conducted extensive studies. Consequently, it was found that defects of the surface configuration of resist patterns are caused by an expansion phenomenon that results from propylene carbonate remaining in the resist pattern during postbaking process. Accordingly, the present invention was accomplished.

Specifically, the present invention provides a photosensitive resin composition including propylene carbonate at a proportion of no greater than 10% by mass. In the photosensitive resin composition provided according to other aspects of the present invention, propylene carbonate is included at a proportion of more preferably no greater than 4% by mass, and the photosensitive resin composition includes propylene carbonate at a proportion of even more preferably no greater than 1% by mass.

### EFFECTS OF THE INVENTION

According to the present invention, a photosensitive resin composition capable of controlling occurrence of defects and capable of forming a favorable pattern configuration, and a method for forming a resist pattern using the same can be provided.

### PREFERRED MODE FOR CARRYING OUT THE INVENTION

Hereinafter, embodiments of the present invention will be explained in detail.

The photosensitive resin composition according to the present invention includes, as component (a), a polyfunctional epoxy resin, and, as component (b), a cation polymerization initiator as essential principal components.

### Propylene Carbonate

The photosensitive resin composition of the present invention is characterized by including propylene carbonate at a proportion of no greater than 10% by mass. More preferably, propylene carbonate is included at a proportion of no greater than 4% by mass, and more preferably, propylene carbonate is included at a proportion of no greater than 1% by mass. Propylene carbonate is an ester based solvent obtained from an alcohol and carbon dioxide (carbonic acid), and also is a refractory solvent having a boiling point of 241.7° C. Thus, propylene carbonate is not volatilized in prebaking carried out in forming the resist film, but remains in the resist film. Therefore, when propylene carbonate is included at a proportion exceeding 10% by mass, as a result of expansion of propylene carbonate remaining in the resist pattern during postbaking process in pattern formation, defects may be caused on the pattern surface.

In general, propylene carbonate is not blended intentionally as a solvent of photosensitive resin compositions. Accordingly, the present inventors thoroughly investigated material systems for the resist composition, and attempts to elucidate the route of contamination with propylene carbonate were conducted to ascertain that propylene carbonate is derived from the solvent for dissolving the cation polymerization initiator (b) described later. Consequently, the present invention was accomplished. More specifically, generally used conventional cation polymerization initiators are soluble only in limited solvents having an extremely strong dissolving power such as propylene carbonate; therefore, they are commonly sold on the market in the state being dissolved in propylene carbonate. Therefore, when such a conventionally known cation polymerization initiator is used, propylene carbonate is included inevitably in the photosensitive resin compositions. In addition, increase in the amount of addition of the cation polymerization initiator dissolved in such a propylene carbonate is required for achieving the sensitivity at a certain level or higher; however, the addition of the cation polymerization initiator in an amount not below a certain level can be the cause of increasing the propylene carbonate concentration in the photosensitive resin composition. In this regard, aspects of the present invention successfully avoid contamination with propylene carbonate by precluding use of a cation polymerization initiator in the state being dissolved in propylene carbonate. Alternatively, aspects of the present invention successfully control the amount of contaminated propylene carbonate by reducing the amount of used cation polymerization initiator used in the state being dissolved in propylene carbonate. Therefore, according to the present invention, by predetermining the content of propylene carbonate to be no greater than 10% by mass, more preferably no greater than 4% by mass, and still more preferably no greater than 1% by mass, occurrence of defects of the pattern surface resulting from an expansion phenomenon of propylene carbonate during postbaking can be precluded, or controlled.

Specifically, since for example, the cation polymerization initiators described later, i.e., diphenyl[4-(phenylthio)phenyl]sulfonium trifluorotrisfluoroalkylphosphate, [4-(phenylthio)phenyl]sulfonium hexafluorophosphate, [4-(phenylthio)phenyl]sulfonium hexafluoroantimonate and the like are available in powder form, contamination with propylene carbonate can be avoided by using any of these cation polymerization initiator alone. In addition, use of any of these cation polymerization initiators in combination with a cation polymerization initiator dissolved in propylene carbonate enables the amount of contamination with propylene carbonate to be reduced. Since the expansion phenomenon of propylene carbonate during postbaking is found markedly in the case of resists of a thick-film type, the present invention is particularly effective in thick-film type resist compositions.

### Polyfunctional Epoxy Resin (a)

It is preferred that the polyfunctional epoxy resin, which is not particularly limited, has sufficient epoxy groups per molecule so as to form a pattern of a thick film. Examples of such polyfunctional epoxy resins include polyfunctional phenol novolac type epoxy resins, polyfunctional orthocresol novolac type epoxy resins, polyfunctional triphenyl type novolac type epoxy resins, polyfunctional bisphenol A novolac type epoxy resins, and the like. Among these, polyfunctional bisphenol A novolac type epoxy resins are preferably used. Preferably, the functionality is at least five, and commercially available examples thereof are “Epicoat 157S70” manufactured by Japan Epoxy Resins Co., Ltd., and “Epichron N-865” manufactured by Dainippon Ink And Chemicals, Incorporated, which are preferably used in particular.

The polyfunctional bisphenol A novolac type epoxy resins described above are represented by the following general formula (1).

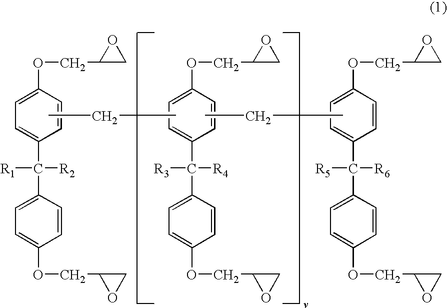

The epoxy group of the bisphenol A novolac type epoxy resin represented by the above general formula (1) may be polymerized with a bisphenol A type epoxy resin or a bisphenol A novolac type epoxy resin. In the above general formula (1), R₁ to R₆ represent a hydrogen atom or a methyl group, and v is 0 or a positive integer.

The content of the polyfunctional epoxy resin in the photosensitive composition is preferably 80% by mass to 99.9% by mass, and more preferably, 92% by mass to 99.4% by mass, based on the entire solid content. Consequently, a photoresist film with higher sensitivity and appropriate hardness may be provided when the resin is coated on the support.

### Cation Polymerization Initiator (b)

As the component (b), diphenyl[4-(phenylthio)phenyl]sulfonium trifluorotrisfluoroalkylphosphate represented by the following general formula (2) is preferably used. As described above, this type of cation polymerization initiator is preferred since it is available in a powdery state, and contamination with propylene carbonate can be avoided or controlled.

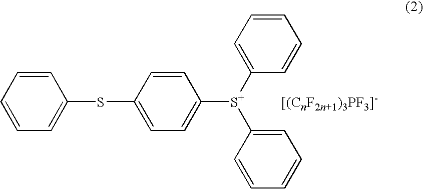

In the above general formula (2), n is preferably 1 to 10, and more preferably 1 to 5.

The cation polymerization initiator as the component (b) may be used alone, or in combination of two or more. Preferably, the proportion of the component (b) blended is 0.1 to 30 parts by mass with respect to 100 parts by mass of the component (a). In light of image formability and resist film formability, the component (b) is particularly preferably used at the proportion of 1 to 20 parts by mass with respect to 100 parts by mass of the component (a).

Alternatively, a well-known cation polymerization initiator may be used in combination, in the photosensitive resin composition as desired, in the range not to impair the effects of the present invention. For example, the cation polymerization initiator represented by the following general formula (3) may be used in combination.

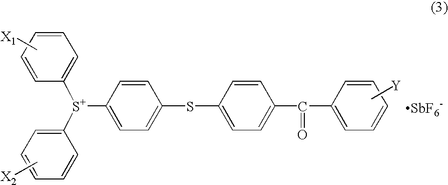

In the above formula (3), X₁ and X₂ represent a hydrogen atom, a hydrogen atom, a hydrocarbon group which may include an oxygen atom or a halogen atom, or an alkoxy group to which a substituent may bond, and may be the same or different one another. Of these, a halogen atom is preferred, and a fluorine atom is more preferable among the halogen atoms.

In the formula (3), Y represents a hydrogen atom, a halogen atom, a hydrocarbon group which may include an oxygen atom or a halogen atom, or an alkoxy group to which a substituent may bond. Among these, Y is preferably a halogen atom, and a chlorine atom is more preferable among the halogen atoms.

Examples of the cation polymerization initiator represented by the above formula (3) include 4-(4-benzoylphenylthio)phenyldiphenylsulfonium hexafluoroantimonate, 4-(4-benzoylphenylthio)phenylbis(4-hydroxyethyloxyphenyl)sulfonium hexafluoroantimonate, 4-(4-benzoylphenylthio)phenylbis(4-fluorophenyl)sulfonium hexafluoroantimonate, 4-(4-benzoylphenylthio)phenylbis(4-chlorophenyl)sulfonium hexafluoroantimonate, 4-{4-(3-chlorobenzoyl)phenylthio}phenylbis(4-fluorophenyl)sulfonium hexafluoroantimonate, 4-(4-benzoylphenylthio)phenylbis(4-methylphenyl)sulfonium hexafluoroantimonate, 4-(4-benzoylphenylthio)phenylbis(4-hydroxyethylphenyl)sulfonium hexafluoroantimonate, 4-{4-(4-hydroxyethyloxybenzoyl)phenylthio}phenylbis(4-fluorophenyl)sulfonium hexafluoroantimonate, 4-{4-(4-hydroxyethyloxybenzoyl)phenylthio}phenyldiphenylsulfonium hexafluoroantimonate, 4-{4-(4-hydroxyethyloxybenzoyl)phenylthio}phenylbis(4-hydroxyethyloxyphenyl)sulfonium hexafluoroantimonate, 4-(4-benzoylphenylthio)phenylbis(4-methoxyethoxyphenyl)sulfonium hexafluoroantimonate, 4-{4-(3-methoxybenzoyl)phenylthio}phenyldiphenylsulfonium hexafluoroantimonate, 4-{4-(3-methoxycarbonylbenzoyl)phenylthio}phenyldiphenylsulfonium hexafluoroantimonate, 4-{4-(2-hydroxymethylbenzoyl)phenylthio}phenyldiphenylsulfonium hexafluoroantimonate, 4-{4-(4-methylbenzoyl)phenylthio}phenylbis(4-fluorophenyl)sulfonium hexafluoroantimonate, 4-{4-(4-methoxybenzoyl)phenylthio}phenylbis(4-fluorophenyl)sulfonium hexafluoroantimonate, 4-{4-(4-fluorobenzoyl)phenylthio}phenylbis(4-fluorophenyl)sulfonium hexafluoroantimonate, and 4-{4-(2-methoxycarbonylbenzoyl)phenylthio}phenylbis(4-fluorophenyl)sulfonium hexafluoroantimonate. Among these compounds, 4-(4-benzoylphenylthio)phenyldiphenylsulfonium hexafluoroantimonate, 4-(4-benzoylphenylthio)phenylbis(4-hydroxyethyloxyphenyl)sulfonium hexafluoroantimonate, 4-(4-benzoylphenylthio)phenylbis(4-fluorophenyl)sulfonium hexafluoroantimonate, 4-(4-benzoylphenylthio)phenylbis(4-chlorophenyl)sulfonium hexafluoroantimonate, and 4-{4-(3-chlorobenzoyl)phenylthio}phenylbis(4-fluorophenyl)sulfonium hexafluoroantimonate are more preferred, and “ADEKAOPTOMER SP-172” manufactured by Asahi Denka Kogyo K.K., [4-{4-(2-chlorobenzoyl)phenylthio}phenylbis(4-fluorophenyl)sulfonium hexafluoroantimonate] is most preferred.

### Other Components

A linear polymeric bifunctional epoxy resin may be additionally contained in the aforementioned photosensitive resin composition of the present invention for improving a film forming property. The linear polymeric bifunctional epoxy resin which may be used is represented by the following general formula (4).

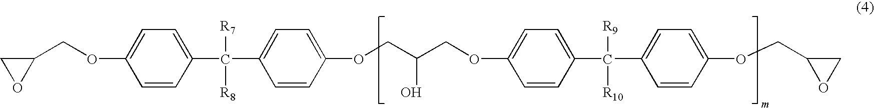

In the above formula (4), R₇ to R₁₀ represent a hydrogen atom or a methyl group, and m is an integer.

The linear polymeric bifunctional epoxy resin, which is not particularly limited, is a product of polymerization of bisphenol A type epoxy or bisphenol F type epoxy, and has an average molecular weight of preferably 2,000 to 7,000 and more preferably 3,000 to 5,000. When the average molecular weight is less than 2,000, the film forming property does not improve, while compatibility with a polyfunctional epoxy resin fails when the average molecular weight is greater than 7,000. Specifically, the bisphenol A type epoxy resin (“Epicoat 1009” manufactured by Japan Epoxy Resins Co., Ltd., average molecular weight: 3,750) is particularly preferable.

A naphthol type sensitizer may be further contained in the photosensitive resin composition of the present invention. When the sensitivity is higher and there exists a gap between a mask and the resist face, the exposure may lead to a phenomenon of thickening of the resultant resin pattern size as compared with the mask size; however, inclusion of the naphthol type sensitizer may suppress the thickening phenomenon without lowering sensitivity. Such addition of the naphthol type sensitizing agent is preferred because an error of the resist pattern dimension with respect to the mask pattern dimension can be reduced.

Examples of the naphthol type sensitizing agent include 1-naphthol, β-naphthol, α-naphthol methyl ether, and α-naphthol ethyl ether. Of these, the most preferred is 1-naphthol in light of the effect of suppressing the thickening phenomenon without lowering the sensitivity.

Too high composition ratio of the naphthol type sensitizing agent in the photosensitive resin composition is not preferred since a reverse taper configuration is provided thereby an excessively thinned line width is given. Taking these into consideration, the naphthol type sensitizing agent is included at a proportion of preferably 0 to 10%, and more preferably, 0.1 to 3%.

A solvent may be further contained in the photosensitive resin composition of the present invention. The sensitivity of the photosensitive resin composition may be enhanced by containing the solvent. Examples of such a solvent may include propylene glycol monomethyl ether acetate (hereinafter, abbreviated as “PGMEA”), methyl isobutyl ketone (hereinafter, abbreviated as “MIBK”), butyl acetate, methyl amyl ketone (2-heptanone), ethyl acetate, and methyl ethyl ketone (hereinafter, abbreviated “MEK”), and the like.

Specifically, γ-butyrolactone is preferred in the case of liquid resists in terms of reacting with and being incorporated in the resist. Moreover, in the case of dry film resists, PGMEA, MIBK, butyl acetate, and MEK are preferred in terms of wettability with a substrate film, and the surface tension.

An oxetane derivative and an epoxy derivative may be further contained in the photosensitive resin composition of the present invention. When a dry film resist is formed, by containing the oxetane derivative or the epoxy derivative, flexibility of the photosensitive resin composition before curing may be enhanced without deteriorating the physical properties of the photosensitive resin composition after the curing. Such an oxetane derivative is not particularly limited, and specific examples thereof may include 3-ethyl-3-hydroxymethyloxetane, 1,4-bis{[(3-ethyl-3-oxetanyl)methoxy]methyl}benzene, di[1-ethyl(3-oxetanyl)]methyl ether, and the like. In addition, the epoxy derivative is exemplified by bisphenol A type epoxy resins, bisphenol F type epoxy resins, etc. having an average molecular weight of 7,000 or less, preferably 2,000 or less, and more preferably 1,000 or less. Specific example thereof may include the bisphenol A type epoxy resin (“Epicoat 828” manufactured by Japan Epoxy Resins Co., Ltd., average molecular weight: 380).

Furthermore, conventionally used miscible additives such as, for example, additional resins, plasticizers, stabilizers, colorants, surfactants, coupling agents and the like for improving performances of the pattern, can be further contained in the photosensitive resin composition of the present invention if desired.

In the mode of using the photosensitive resin composition of the present invention, the solution may be applied to form a cured film which may be used, alternatively, a dry film may be formed by protecting each side of a layer formed from the photosensitive resin composition with a resin film, and adhered on a desired support prior to pattern exposure. When a polyethylene terephthalate film is used as one of the protective films, it is preferable to use any of polymeric films such as a polyethylene terephthalate film, polypropylene film and polyethylene film as another protective film.

Supply of the photosensitive resin composition in the form of a film as described above enables the steps of application on a support and drying to be eliminated, whereby the formation of a pattern can be simplified.

A photosensitive resin composition layer is formed by dissolving the photosensitive resin composition of the present invention in a solvent, applying on a substrate such as, for example, a silicon wafer or the like with a spin coater etc., followed by drying. Subsequently, this resin composition layer is subjected to pattern exposure with a radiation, and a development process is carried out with a developing solution after the exposure. Accordingly, a favorable resin pattern can be formed in a manner faithfully following the mask pattern without depending on the support employed.

Alternatively, a laminated photosensitive resin composition layer is obtained by molding the photosensitive resin composition of the present invention into a dry film shape, and attaching onto a desired support. Next, this laminated photosensitive resin composition layer is subjected to pattern exposure with a radiation, and a development process is carried out with a developing solution. Accordingly, a favorable resin pattern can be formed in a manner faithfully following the mask pattern without depending on the support employed. Thus, for example, it becomes possible to realize the formation of the precision minute space provided required for formation of electronic devices such as inkjet recording heads, with excellent dimension stability.

### EXAMPLES

### Examples 1 to 6, and Comparative Example 1

According to the formulations shown in Table 1 (the units are based on part by mass), a polyfunctional epoxy resin, a cation polymerization initiator, a solvent, and other components were blended to obtain photosensitive resin compositions.

The photosensitive resin compositions were uniformly applied on a polyethylene terephthalate (PET) film having a film thickness of 50 μm provided with a release agent (support film, manufactured by Teijin DuPont Limited), and dried with a hot-air convective dryer at 60° C. for 10 minutes. Results obtained by measuring the amount of propylene carbonate remaining in the photoresist layer after drying are shown in Table 1.

Similarly, the photosensitive resin compositions prepared according to the formulation shown in Table 1 were applied to a silicon wafer by means of a spin coater, and then dried, thereby obtaining a photosensitive resin layer having a film thickness of 30 μm. The photosensitive resin composition layer was prebaked on a hot plate at 60° C. for 5 min, and at 90° C. for 10 min. After the prebaking, pattern exposure (soft contact, ghi ray) was carried out using PLA-501F (contact aligner, manufactured by Canon Inc.), and then post-exposure baking (PEB) was carried out at 90° C. for 5 minutes using a hot plate. Then, a developing process was carried out for 8 minutes by an immersion process using PGMEA. Next, the developed resin pattern was post-baked together with the substrate at 200° C. for 1 hour using an oven to obtain a resin pattern hardened on the substrate.

As a result, any defect due to expansion was not found on the cured resin pattern obtained using the photosensitive resin composition of Example 1. To the contrary, a defect due to expansion was observed on the cured resin pattern obtained using the photosensitive resin composition of Comparative Example 1.

TABLE 1

| | | | | | | | | Comparative |
|---|---|---|---|---|---|---|---|---|
| | Blended | Example | | | | | | Example |
| | component | 1 | 2 | 3 | 4 | 5 | 6 | 1 |
| Polyfunctional epoxy resin | A-1 | 100 | 100 | — | 80 | 100 | 90 | 100 |
| | A-2 | — | — | 100 | — | — | — | — |
| Cation polymerization initiator | B-1 | 3 | 3 | 3 | 3 | — | — | — |
| | B-2 | — | — | — | — | 5 | 5 | — |
| | B-3 | — | — | — | — | — | — | 5 |
| Bifunctional epoxy resin | C | — | — | — | 20 | — | — | — |
| Sensitizing agent | D-1 | — | 1 | 1 | 1 | 1 | 1 | — |
| Solvent | E-1 | 50 | 50 | 50 | 50 | 50 | 50 | 50 |
| Others | F | — | — | — | — | — | 10 | — |
| | G | — | — | — | — | 1 | 1 | — |

| | | | | | | | |
|---|---|---|---|---|---|---|---|
| Remaining propylene carbonate | <1 | <1 | <1 | <1 | <1 | <1 | 30 |

(A-1): Polyfunctional bisphenol A novolac type epoxy resin: JER157S70 (manufactured by Japan Epoxy Resins Co., Ltd., trade name)
(A-2): Polyfunctional bisphenol A novolac type epoxy resin: Epichron N-865 (manufactured by Dainippon Ink And Chemicals, Incorporated, trade name)
(B-1): Cation polymerization initiator: diphenyl[4-(phenylthio)phenyl]sulfonium trifluorotrispentafluoroethylphosphate
(B-2): Cation polymerization initiator: diphenyl[4-(phenylthio)phenyl]sulfonium hexafluoroantimonate
(B-3): Cation polymerization initiator: diphenyl[4-(phenylthio)phenyl]sulfonium hexafluorophosphate
(C): Bifunctional epoxy resin: JER1004 (manufactured by Japan Epoxy Resins Co., Ltd., trade name)
(D-1): Sensitizing agent: 2,3-dihydroxynaphthalene
(D-2): Sensitizing agent: 1,5-dihydroxynaphthalene
(E): γ-butyrolactone
(F): Oxetane derivative: 1,4-bis{[(3-ethyl-3-oxetanyl)methoxy]methyl}benzene
(G): Leveling agent: Paintad M (manufactured by Dow Corning Corp., trade name)

### INDUSTRIAL APPLICABILITY

As in the foregoing, the photosensitive resin composition according to the present invention is useful for forming micro resist patterns having a large film thickness and a high aspect ratio, and in particular, occurrence of defects can be controlled and a favorable pattern configuration can be formed.

1. A photosensitive resin composition comprising: as component (a), a polyfunctional epoxy resin; and, as component (b), a cation polymerization initiator, wherein
a concentration of propylene carbonate in the photosensitive resin composition is no greater than 10% by mass.

2. The photosensitive resin composition according to claim 1, wherein the concentration of propylene carbonate is no greater than 4% by mass.

3. The photosensitive resin composition according to claim 1, wherein the concentration of propylene carbonate is no greater than 1% by mass.

4. The photosensitive resin composition according to claim 1, wherein the cation polymerization initiator is at least one selected from the group consisting of diphenyl[4-(phenylthio)phenyl]sulfonium trifluorotrisfluoroalkylphosphate, [4-(phenylthio)phenyl]sulfonium hexafluorophosphate, and [4-(phenylthio)phenyl]sulfonium hexafluoroantimonate.

5. The photosensitive resin composition according to claim 1, wherein the polyfunctional epoxy resin is a polyfunctional bisphenol A novolac type epoxy resin.

6. A photosensitive dry film configured by forming a protective film on each side of a layer formed from the photosensitive resin composition according to claim 1.

7. A method for forming a resist pattern, wherein a cured resin pattern of a predetermined shape is obtained by applying the photosensitive resin composition according to claim 1 on a support, drying, and exposing to obtain a predetermined pattern, followed by heat-treating the resin pattern obtained by development.

8. A method for forming a pattern, wherein a cured resin pattern of a predetermined shape is obtained by attaching the photosensitive dry film according to claim 6 onto a support, exposing to obtain a predetermined pattern, followed by heat-treating the resin pattern obtained by development.
